(19) United States
(12) Patent Application Publication
(10) Pub. No.: US 2018/0097043 A1
(43) Pub. Date: Apr. 5, 2018

(54) HEAD-MOUNTED DISPLAY DEVICE

(71) Applicant: SAMSUNG DISPLAY CO., LTD., Yongin-si (KR)

(72) Inventor: Joon Hee SONG, Chungcheongnam-do (KR)

(21) Appl. No.: 15/718,219

(22) Filed: Sep. 28, 2017

(30) Foreign Application Priority Data
Oct. 5, 2016 (KR) 10-2016-0128482

(51) Int. Cl. H01L 27/32; H01L 25/065

(52) U.S. Cl. CPC H01L 27/3218; H01L 27/3216; H01L 25/0655; H01L 27/3276; H01L 27/3246

(57) ABSTRACT

A head-mounted display device includes a case, a display panel, and an optical system to enlarge the image. Each of the pixels of the display panel includes a plurality of first subpixels, a plurality of second subpixels, and a plurality of third subpixels. The first subpixels are connected to each other, the second subpixels are connected to each other, and the third subpixels are connected to each other. The first subpixels, the second subpixels, and the third subpixels emit light of different colors.

### CROSS-REFERENCE TO RELATED APPLICATION

Korean Patent Application No. 10-2016-0128482 filed on Oct. 5, 2016, and entitled: “Head-Mounted Display Device,” is incorporated by reference herein in its entirety.

### BACKGROUND

### 1. Field

One or more embodiments herein relate to a head-mounted display device.

### 2. Description of the Related Art

Head-mounted display devices are used in a variety of applications, not the least of which include virtual reality (VR) and augmented reality (AR) systems. A head-mounted display device includes an optical system between a display panel and the eyes of a user. The optical system enlarges images displayed on the display panel for viewing. However, enlarging the image may increase give the appearance of a reduced number of pixels per inch. Thus, the displayed image may be perceived to have low resolution.

### SUMMARY

In accordance with one or more embodiments, a head-mounted display device includes a case; a display panel in the case to display an image; and an optical system to enlarge the image, wherein: the display panel includes a plurality of pixels; each of the pixels includes a plurality of first subpixels, a plurality of second subpixels, and a plurality of third subpixels; the first subpixels are connected to each other, the second subpixels are connected to each other, and the third subpixels are connected to each other; and the first subpixels, the second subpixels, and the third subpixels are to emit light of different colors.

Each of the pixels may include two of the first subpixels, four of the second subpixels, and two of the third subpixels. The four second subpixels may surround one of the two first subpixels, and the two first subpixels and two third subpixels may alternately surround one of the four second subpixels. One of the two first subpixels may be connected to a first data line, one of the four second subpixels may be connected to a second data line, and one of the two third subpixels may be connected to third data line.

One of the four second subpixels and the two first subpixels may be connected to a first scan line, and another of the four second subpixels and the two third subpixels may be connected to a second scan line. One of the two first subpixels may be connected to a sixth data line and the other of the two first subpixels is connected to an eighth data line, the four second subpixels may be connected to a seventh data line, one of the two third subpixels may be connected to the sixth data line and the other of the two third subpixels is connected to the eighth data line.

Two of the four second subpixels, one of the two first subpixels, and one of the two third subpixels may be connected to a third scan line, and the other two of the four second subpixels, the other one of the two first subpixels, and the other one of the two third subpixels may be connected to a fourth scan line. The first subpixels may emit red light, the second subpixels may emit green light, and third subpixels may emit blue light.

The display panel may include a substrate; a circuit portion on the substrate; a plurality of electrodes connected to the circuit portion; a pixel defining layer including a plurality of pixel openings; a common electrode facing the electrodes; and a plurality of organic emission layers, each of the organic emission layers between one of the electrodes and the common electrode, wherein the first subpixels, the second subpixels, and the third subpixels are to emit the light of the different colors through respective ones of the pixel openings, and wherein sizes of the first subpixels, the second subpixels, and third subpixels correspond to sizes of the respective ones of the pixel openings.

The display panel may include a first display panel corresponding to a left-eye position and a second display panel corresponding to a right-eye position, the optical system may include a first optical system corresponding to the first display panel and a second optical system corresponding to the second display panel, a length of the first display panel may be longer than a diameter of the first optical system, and a length of the second display panel may be longer than a diameter of the second optical system.

A distance from the first optical system to the first display panel may be larger than a distance from the left-eye position to the first optical system, and a distance from the second optical system to the second display panel may be larger than a distance from the right-eye position to the second optical system. Each of the pixels may include two of the first subpixels, two of the second subpixels is two, and two of the third subpixels. One of the two third subpixels may be between the two first subpixels and between the two second subpixels.

In accordance with one or more other embodiments, a pixel includes a plurality of first subpixels; a plurality of second subpixels; and a plurality of third subpixels, wherein: the first subpixels are connected to each other, the second subpixels are connected to each other, and the third subpixels are connected to each other; and the first subpixels, the second subpixels, and the third subpixels are to emit light of different colors. The pixel may include two of the first subpixels, four of the second subpixels, and two of the third subpixels. The pixel may include two of the first subpixels, two of the second subpixels, and two of the third subpixels.

At least two of the first subpixels, the second subpixels, or the third subpixels may have different areas. At least two of the first subpixels, the second subpixels, or the third subpixels may have different shapes. At least two of the first subpixels, the second subpixels, and the third sub pixels may be spaced at different distances. At least one of the second subpixels may be between adjacent ones of the first sub pixels or adjacent ones of the second subpixels.

### BRIEF DESCRIPTION OF THE DRAWINGS

Features will become apparent to those of skill in the art by describing in detail exemplary embodiments with reference to the attached drawings in which:

FIG. 1 illustrates an embodiment of a head-mounted display device;

FIG. 2 illustrates an embodiment of a display panel;

FIG. 3 illustrates a view along section line in FIG. 2;

FIG. 4 illustrates an embodiment of a pixel;

FIG. 5 illustrates another embodiment of a pixel;

FIG. 6 illustrates another embodiment of a display panel;

FIG. 7 illustrates another embodiment of a pixel; and

FIG. 8 illustrates another embodiment of a display panel.

### DETAILED DESCRIPTION

Example embodiments are described with reference to the drawings; however, they may be embodied in different forms and should not be construed as limited to the embodiments set forth herein. Rather, these embodiments are provided so that this disclosure will be thorough and complete, and will convey exemplary implementations to those skilled in the art. The embodiments (or portions thereof) may be combined to form additional embodiments

In the drawings, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

When an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

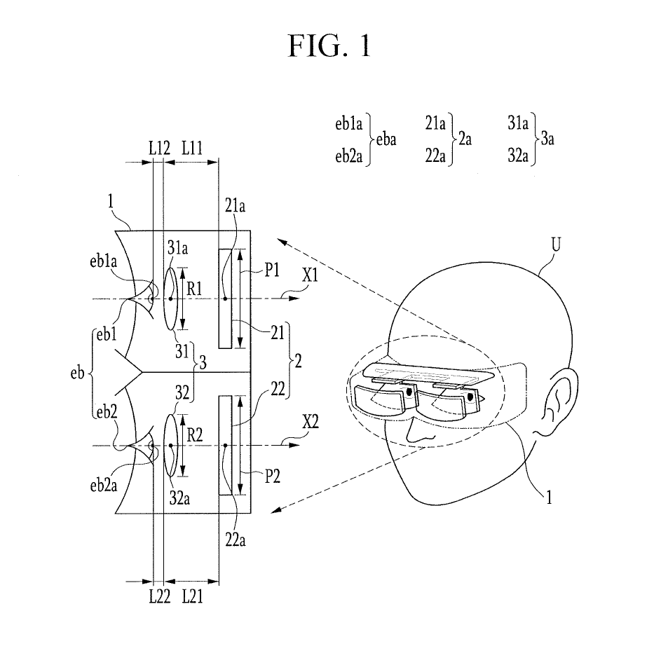

FIG. 1 illustrates an embodiment of a head-mounted display device which includes a case 1, a display panel 2, and an optical system 3. The head-mounted display device is mounted on a head of a user U and displays an image to eyes eb of the user U, that is, to a left eye eb1 and a right eye eb2.

The case 1 supports the display panel 2 and the optical system 3 and is mounted on the head of the user U. The case 1 may have any of a number of shapes as long as it may be mounted on the head of the user U while supporting the display panel 2 and the optical system 3. The case 1 may have, for example, an eyeglass shape, a helmet shape, or the like.

The display panel 2 is inside the case 1 and displays an image. The display panel 2 includes a first display panel 21 corresponding to the left eye eb1 of the user U and a second display panel 22 corresponding to the right eye eb2 of the user U. The first display panel 21 and the second display panel 22 may display the same image. The display panel 2 may be, for example, an organic light emitting diode (OLED) panel or a liquid crystal display (LCD) panel.

The optical system 3 faces the display panel 2 and enlarges the image displayed on the display panel 2 in the direction of the eyes eb of the user U. The optical system 3 is between the display panel 2 and the user U. The optical system 3 includes a first optical system 31 corresponding to the first display panel 21 and a second optical system 32 corresponding to the second display panel 22.

The length P1 of the first display panel 21 may be longer than a diameter R1 of the first optical system 31. The length P2 of the second display panel 22 is longer than a diameter R2 of the second optical system 32. The distance L11 from the first optical system 31 to the first display panel 21 may be larger than the distance L12 from the left eye eb1 of the user U to the first optical system 31. The distance L21 from the optical system 32 to the second display panel 22 may be larger than a distance L22 from the right eye eb2 of the user U to the second optical system 32.

By positioning optical system 3 between the eyes eb of the user U and the display panel 2, the display panel 2 may be easily viewed close to the eyes eb of user U.

The optical system 3 may include a convex lens that is convex toward the display panel 2. The optical system 3 may include a concave lens to correct a distortion caused by the convex lens. The concave lens may be, for example, an aspherical lens.

A central portion 2a of the display panel 2 may correspond to a center eba of the eyes eb of the user U. In addition, the central portion 2a of the display panel 2 may correspond to a center 3a of the optical system 3. For example, a center portion 21a of the first display panel 21, a center 31a of the first optical system 31, and a center eb1a of the left eye eb1 may be respectively positioned on a first optical path X1. Similarly, a center portion 22a of the second display panel 22, a center 32a of the second optical system 32, and a center eb2a of the right eye eb2 may be respectively positioned on a second optical path X2.

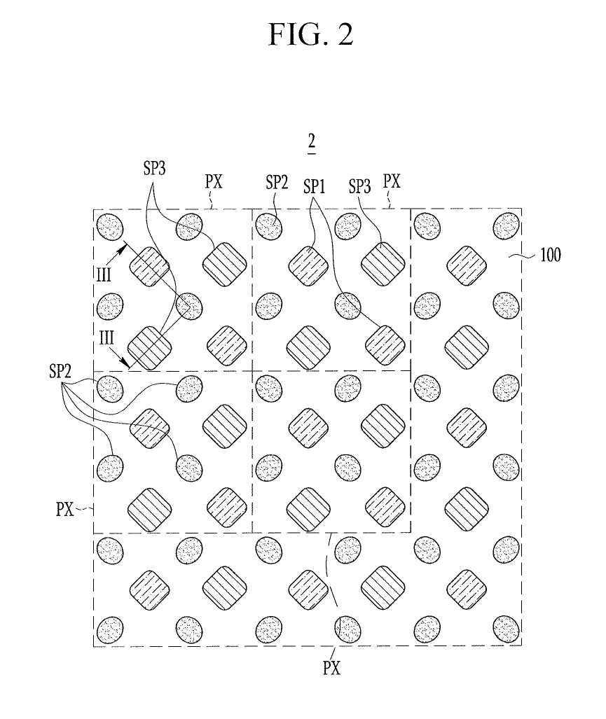

FIG. 2 illustrates a top plan view of an embodiment of a display panel 2 of the head-mounted display device of FIG. 1. Referring to FIG. 2, the display panel 2 includes a pixel layer 100 provided with a plurality of pixels PX.

Each of the pixels PX includes a plurality of first subpixels SP1, a plurality of second subpixels SP2, and a plurality of third subpixels SP3. The first subpixels SP1, the second subpixels SP2, and the third subpixels SP3 may form one pixel PX to display a part of an image using light emitted by the first subpixels SP1, the second subpixels SP2, and the third subpixels SP3. The image may be displayed by the pixels PX.

In one embodiment, one pixel PX may include two first subpixels SP1, four second subpixels SP2, and two third subpixels SP3. That is, one pixel PX may include eight subpixels SP1, SP2, and SP3. In some exemplary embodiments, four, five, six, seven, nine, ten, eleven, or twelve subpixels may form one pixel.

The number of pixels PX may be, for example, 1280*720, 1366*768, 1920*1080, or 3840*2160 in the display panel 2. One pixel PX may include the two first subpixels SP1, the four second subpixels SP2, and the two third subpixels SP3, but may include a different number or combination of subpixels in another embodiment.

The first subpixel SP1, the second subpixel SP2, and the third subpixel SP3 emit light of different colors. For example, the first subpixel SP1 emits red light, the second subpixel SP2 emits green light, and the third subpixel SP3 emits blue light. In one pixel PX, the four second subpixels SP2 surround one of the two first subpixels SP1, and the two first subpixels SP1 and the two third subpixels SP3 alternately surround one of the four second subpixels SP2. The first subpixels SP1, the second subpixels SP2, and the third subpixels SP3 may be disposed in a different combination in another embodiment.

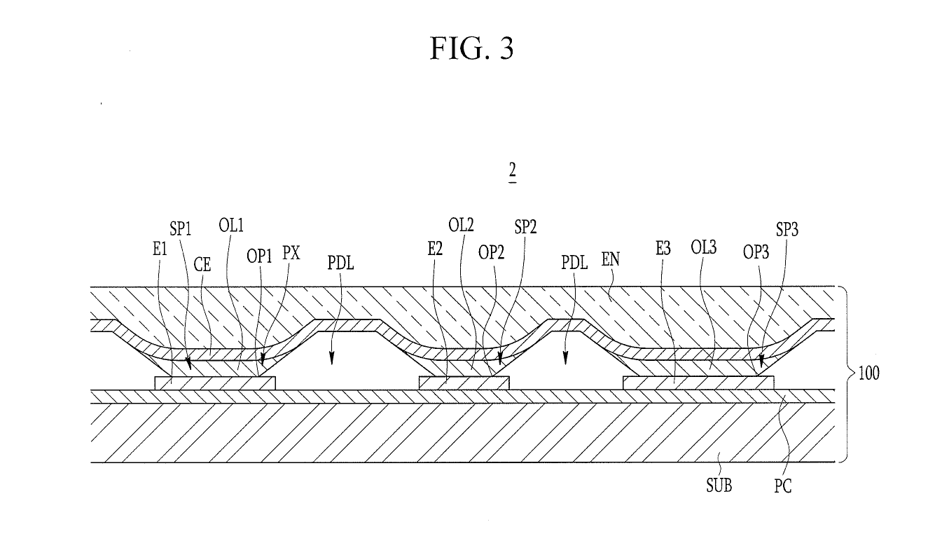

FIG. 3 illustrates a cross-sectional view taken along line of FIG. 2. Referring to FIG. 3, the pixel layer 100 includes a substrate SUB, a circuit portion PC, a first electrode E1, a second electrode E2, a third electrode E3, a pixel defining layer PDL, a first organic emission layer OL1, a second organic emission layer OL2, a third organic emission layer OL3, a common electrode CE, and an encapsulation portion EN.

The substrate SUB may be an insulating substrate made of glass, quartz, ceramics, plastic, or the like. In addition, the substrate SUB may be flexible, stretchable, rollable, and foldable together with an organic light emitting display.

The circuit portion PC is on the substrate SUB and includes a number of wires, e.g., at least one scan line, a data line, a driving power line, a common power line, and an initialization power line. A pixel circuit may include one or more thin film transistors (TFTs) and at least one capacitor connected to wires corresponding to one subpixel.

The first electrode E1 is on the circuit portion PC and is connected to the thin film transistor of the circuit portion PC. A central area of the first electrode E1 overlaps a first pixel opening OP1 of the pixel defining layer PDL. For example, the first electrode E1 is opened by the first pixel opening OP1.

The second electrode E2 is on the circuit portion PC and is spaced apart from the first electrode E1. The second electrode E2 is connected to the thin film transistor of the circuit portion PC. A central area of the second electrode E2 overlaps a second pixel opening OP2 of the pixel defining layer PDL. For example, the second electrode E2 is opened by the second pixel opening OP2.

The third electrode E3 is on the circuit portion PC to be spaced apart from the first electrode E1 and the second electrode E2. The third electrode E3 is connected to the thin film transistor of the circuit portion PC. A central area of the third electrode E3 overlaps a third pixel opening OP3 of the pixel defining layer PDL. For example, the third electrode E3 is opened by the third pixel opening OP3.

Each of the first electrode E1, the second electrode E2, and the third electrode E3 may be an anode electrode corresponding to a hole injection electrode or a cathode electrode corresponding to an electron injection electrode. Each of the first electrode E1, the second electrode E2, and the third electrode E3 may be a light-transmitting electrode or a light-reflecting electrode.

The pixel defining layer PDL is on the first electrode E1, the second electrode E2, and the third electrode E3, and covers respective edges of the first electrode E1, the second electrode E2, and the third electrode E3.

The pixel defining layer PDL includes the first pixel opening OP1, the second pixel opening OP2, and the third pixel opening OP3. The first pixel opening OP1, the second pixel opening OP2, and the third pixel opening OP3 may have, for example, planar shapes of different areas.

The first pixel opening OP1 overlaps the first electrode E1, the second pixel opening OP2 overlaps the second electrode E2, and the third pixel opening OP3 overlaps the third electrode E3. Each of the first pixel opening OP1, the second pixel opening OP2, and the third pixel opening OP3 have a predetermined shape, e.g., a planar polygonal shape such as a triangle, a quadrangle, a pentagon, a hexagon, a heptagon, and an octagon in a planar view, a planar circular shape, a planar elliptical shape, or a planar closed loop shape.

An area of the first pixel opening OP1 may be larger than an area of the second pixel opening OP2. An area of the third pixel opening OP3 may be larger than an area of the first pixel opening OP1. The first pixel opening OP1 defines an area and planar shape of the first subpixel SP1. The size of the first pixel opening OP1 corresponds to that of the first subpixel SP1.

The first subpixel SP1 may define an area in which light emitted by the first electrode E1, the first organic emission layer OL1, and the common electrode CE is emitted through the first pixel opening OP1 of the pixel defining layer PDL.

The second pixel opening OP2 defines an area and planar shape of the second subpixel SP2. The size of the second pixel opening OP2 corresponds to that of the second subpixel SP2.

The second subpixel SP2 may define an area in which light emitted by the second electrode E2, the second organic emission layer OL2, and the common electrode CE is emitted through the second pixel opening OP2 of the pixel defining layer PDL.

The third pixel opening OP3 defines an area and planar shape of the third subpixel SP3. The size of the third pixel opening OP3 corresponds to that of the third subpixel SP3.

The third subpixel SP3 may define an area in which light emitted by the third electrode E3, the third organic emission layer OL3, and the common electrode CE is emitted through the third pixel opening OP3 of the pixel defining layer PDL.

The first organic emission layer OL1 is on the first electrode E1 corresponding to the first pixel opening OP1. The first organic emission layer OL1 includes an organic material that emits red light. A portion of the first organic emission layer OL1 is positioned in the first pixel opening OP1 to contact the first electrode E1 and emits red light. For example, the first organic emission layer OL1 emits red light in the planar shape of the first pixel opening OP1. In one embodiment, the first organic emission layer OL1 may include an organic material emitting blue light, green light, or white light. In this case, a portion of the first organic emission layer OL1 is positioned in the first pixel opening OP1 to contact the first electrode E1 and may emit blue light, green light, or white light.

The second organic emission layer OL2 is on the second electrode E2 corresponding to the second pixel opening OP2. The second organic emission layer OL2 includes an organic material that emits green light. A portion of the second organic emission layer OL2 is positioned in the second pixel opening OP2 to contact the second electrode E2 and emits green light. For example, the second organic emission layer OL2 emits green light in the planar shape of the second pixel opening OP2. In one embodiment, the second organic emission layer OL2 may include an organic material emitting red light, blue light, or white light. In this case, a portion of the second organic emission layer OL2 is positioned in the second pixel opening OP2 to contact the second electrode E2 and may emit red light, blue light, or white light.

The third organic emission layer OL3 is on the third electrode E3 corresponding to the third pixel opening OP3. The third organic emission layer OL3 includes an organic material that emits blue light. A portion of the third organic emission layer OL3 is positioned in the third pixel opening OP3 to contact the third electrode E3 and emits blue light. For example, the third organic emission layer OL3 emits blue light in the planar shape of the third pixel opening OP3. In one embodiment, the third organic emission layer OL3 may include an organic material emitting red light, green light, or white light. In this case, a portion of the third organic emission layer OL3 is positioned in the third pixel opening OP3 to contact the third electrode E3 and may emit red light, green light, or white light.

The first organic emission layer OL1, the second organic emission layer OL2, and the third organic emission layer OL3 may be respectively deposited on the first pixel opening OP1, the second pixel opening OP2, and the third pixel opening OP3 through an opening pattern formed in a fine metal mask.

The common electrode CE is on the first organic emission layer OL1, the second organic emission layer OL2, and the third organic emission layer OL3 across an entire surface of the substrate SUB. The common electrode CE may be a cathode electrode corresponding to an electron injection electrode or an anode electrode corresponding to a hole injection electrode. The common electrode CE may be a light-transmitting electrode or a light-semi-transmitting electrode.

The encapsulation portion EN is on the common electrode CE and seals the first organic emission layer OL1, the second organic emission layer OL2, and the third organic emission layer OL3 together with the substrate SUB. The encapsulation portion EN may correspond to a thin film encapsulation layer or an encapsulation substrate.

In the head-mounted display device of the present exemplary embodiment, when the image displayed on the display panel 2 is enlarged by the optical system and provided to the user, since one pixel PX in the display panel 2 includes the plurality of first subpixels SP1, the plurality of second subpixels SP2, and the plurality of third subpixels SP3, distances between the subpixels in the display panel 2 are recognized to be relatively small by the user. Thus, the display panel 2 is recognized by the user as having a high number of pixels per inch (PPI).

For example, since one pixel PX in the display panel 2 includes two first subpixels SP1, four second subpixels SP2, and two third subpixels SP3, that is, eight subpixels, the number of PPI of the display panel 2 is recognized as high by the user when the image displayed on the display panel 2 is enlarged by the optical system 3 for viewing. That is, according to the current exemplary embodiment, it is possible to provide a head-mounted display device with improved resolution.

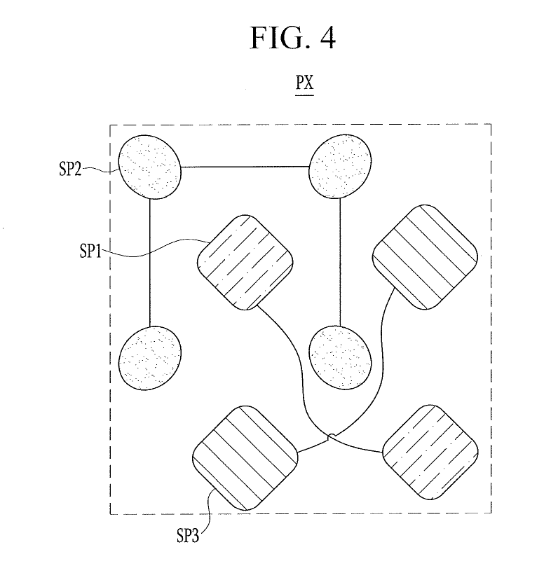

FIG. 4 illustrates a top plan view of another embodiment of a pixel PX, which may be representative of the pixels a display panel of a head-mounted display device. Referring to FIG. 4, the pixel PX includes a plurality of first subpixels SP1, a plurality of second subpixels SP2, and a plurality of third subpixels SP3.

The first subpixels SP1, the second subpixels SP2, and the third subpixels SP3 form one pixel PX emits light to display a portion of an image. In one embodiment, the pixel PX may include two first subpixels SP1, four second subpixels SP2, and two third subpixels SP3. That is, the pixel PX may include eight subpixels.

The two first subpixels SP1 may be connected to each other, the four second subpixels SP2 may be connected to each other, and the two third subpixels SP3 may be connected to each other. Thus, the two first subpixels SP1 may simultaneously emit light, the four second subpixels SP2 may simultaneously emit light, and the two third subpixels SP3 may simultaneously emit light.

For example, the first electrodes of the two first subpixels SP1 may be connected to each other. The second electrodes of the four second subpixels SP2 may be connected to each other The third electrodes of the two third subpixels SP3 may be connected to each other.

As such, in the head-mounted display device according to the present exemplary embodiment, when the image displayed on the display panel is enlarged by the optical system for viewing, the distances between the subpixels in the display panel are recognized to be relatively small by the user. This is because the pixel PX in the display panel includes a plurality of each of the first, second, and third subpixels SP1, SP2, and SP3 which emit light at the same time. Thus, the display panel is recognized by the user as having a high number of pixels per inch (PPI).

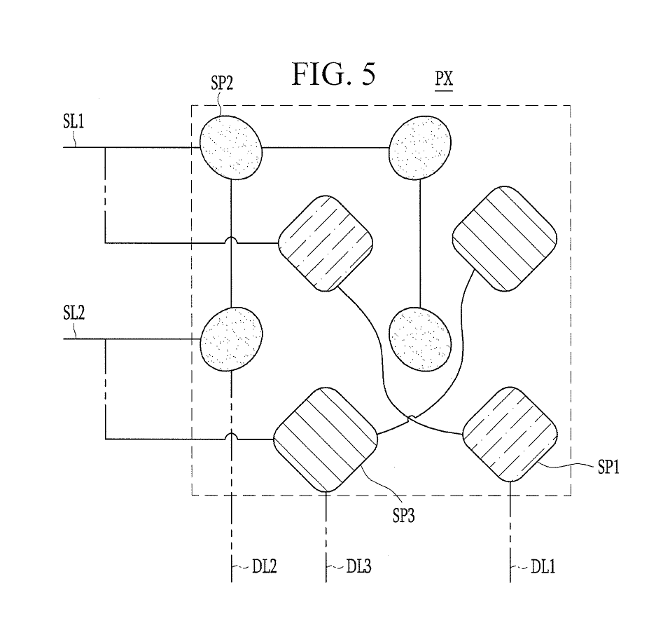

FIG. 5 illustrates a top plan view of another embodiment of a pixel of a display panel of a head-mounted display device. Portions that are different from the head-mounted display device of FIG. 4 will be described.

Referring to FIG. 5, in the pixel PX of the present exemplary embodiment, one of two first subpixels SP1 is connected to a first data line DL1, one of four second subpixels SP2 is connected to a second data line DL2, and one of two third subpixels SP3 is connected to a third data line DL3. Each of the first data line DL1, the second data line DL2, and the third data line DL3 may be, for example, a data line among wires in the circuit portion. The first data line DL1, the second data line DL2, and the third data line DL3 may be respectively connected to the first electrode of the first subpixel SP1, the second electrode of the second subpixel SP2, and the third electrode of the third subpixel SP3 through the pixel circuit of the circuit portion.

Each of the first subpixel SP1, the second subpixel SP2, and the third subpixel SP3 may emit light with luminance corresponding to a data voltage applied to each of the first data line DL1, the second data line DL2, and the third data line DL3.

The first scan line SL1 is connected to one of the four second subpixels SP2 and the two first subpixels SP1. The second scan line SL2 is connected to another one of the four second subpixels SP2 and the two third subpixels SP3. Each of the first scan line SL1 and the second scan line SL2 may be, for example, a scan line among the wires in the circuit portion.

The first scan line SL1 and the second scan line SL2 switch the pixel circuit of the circuit portion to selectively turn on at least one of the two first subpixels SP1, the four second subpixels SP2, or the two third subpixels SP3. In this case, the first data line DL1 transmits the same data voltage to the two first subpixels SP1, the second data line DL2 transmits the same data voltage to the four second subpixels SP2, and the third data line DL3 transmits the same data voltage to the two third subpixels SP3.

The first data line DL1 may transmit a data voltage corresponding to one half of red luminance to be emitted from one pixel PX to the two first subpixels SP1. The second data line DL2 may transmit a data voltage corresponding to one fourth of green luminance to be emitted from one pixel PX to the four second subpixels SP2. The third data line DL2 may transmit a data voltage corresponding to one half of blue luminance to be emitted from one pixel PX to the two third subpixels SP3.

As such, in the head-mounted display device according to the present exemplary embodiment, Only three data lines (the first data line DL1, the second data line DL2, and the third data line DL3) corresponding to red, green, and blue light are included for the pixel. This is so even though one pixel PX includes eight subpixels (e.g., two first subpixels SP1, the four second subpixels SP2, and the two third subpixels SP3). Thus, an additional data line and an additional data driver for generating an additional data voltage are not required.

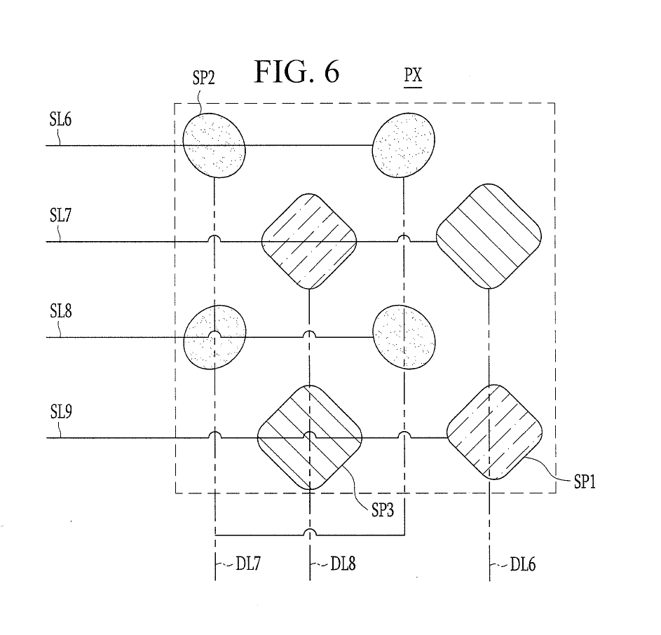

FIG. 6 illustrates a top plan view of another embodiment of a pixel of a display panel of a head-mounted display device. Portions that are different from the head-mounted display device according to the exemplary embodiment described above will now be described.

Referring to FIG. 6, in the pixel PX of the present exemplary embodiment, one of the two first subpixels SP1 is connected to a sixth data line DL6, and the other thereof is connected to an eighth data line DL8. In addition, the four second subpixels SP2 are connected to a seventh data line DL7, one of the two third subpixels SP3 is connected to the sixth data line DL6, and the other is connected to the eighth data line DL8.

Each of the sixth data line DL6, the seventh data line DL7, and the eighth data line DL8 may be, for example, a data line among the wires in the circuit portion. The sixth data line DL6 may be connected to the first electrode of the first subpixel SP1 and the third electrode of the third subpixel SP3 through the pixel circuit of the circuit portion. The seventh data line DL7 may be connected to the second electrode of the second subpixel SP2 through the pixel circuit of the circuit portion. The eighth data line DL8 may be connected to the first electrode of the first subpixel SP1 and the third electrode of the third subpixel SP3 through the pixel circuit of the circuit portion.

The first subpixel SP1 and third subpixel SP3 may emit light with luminance corresponding to a data voltage applied to each of the sixth data line DL6 and the eighth data line DL8. The second subpixel SP2 may emit light with luminance corresponding to a data voltage applied to the seventh data line DL7.

Two second subpixels SP2 are connected to a sixth scan line SL6. The first subpixel SP1 and the third subpixel SP3 are connected to a seventh scan line SL7. The other two second subpixels SP2 are connected to an eighth scan line SL8. The third subpixel SP3 and the first subpixel SP1 are connected to a ninth scan line SL9.

Each of the sixth scan line SL6 to the ninth scan line SL9 may be, for example, at least one scan line among the wires in the circuit portion. The sixth scan line SL6 to the ninth scan line SL9 switch the pixel circuit of the circuit portion to selectively turn on at least one of the two first subpixels SP1, the four second subpixels SP2, or the two third subpixels SP3. In this case, the sixth data line DL6 and the eighth data line DL8 transmit the same data voltage to the two first subpixels SP1, the seventh data line DL7 transmits the same data voltage to the four second subpixels SP2, and the sixth data line DL6 and the eighth data line DL8 transmit the same data voltage to the two third subpixels SP3.

The sixth data line DL6 and the eighth data line DL8 may transmit a data voltage corresponding to one half of red luminance to be emitted from one pixel PX to the two first subpixels SP1. The seventh data line DL7 may transmit a data voltage corresponding to one fourth of green luminance to be emitted from one pixel PX to the four second subpixels SP2. The sixth data line DL6 and the eighth data line DL8 may transmit a data voltage corresponding to one half of blue luminance to be emitted from one pixel PX to the two third subpixels SP3.

As such, in the head-mounted display device according to the present exemplary embodiment, even though pixel PX includes eight subpixels (two first subpixels SP1, the four second subpixels SP2, and the two third subpixels SP3), since only three data lines including the sixth data line DL6, the seventh data line DL7, and the eighth data line DL8 corresponding to red, green, and blue light are included therein, an additional data line and an additional data driver for generating an additional data voltage are not required.

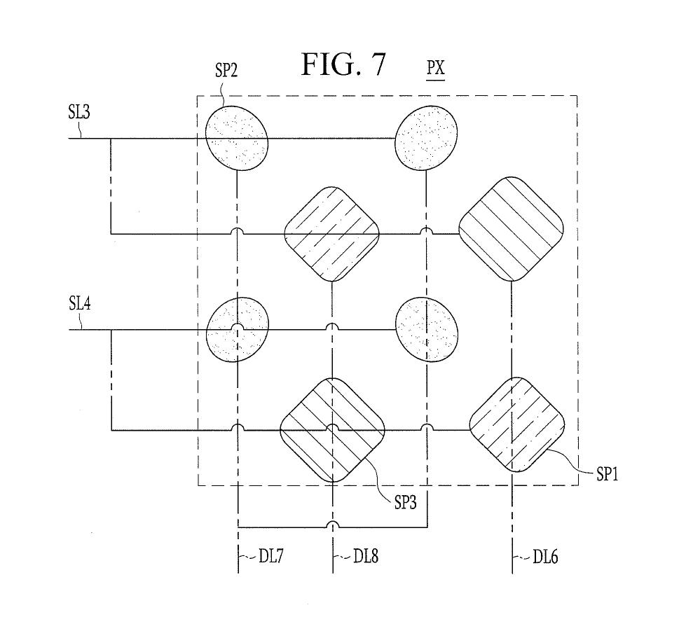

FIG. 7 illustrates a top plan view of another embodiment of a pixel of a display panel of a head-mounted display device. Portions that are different from the head-mounted display device according to the exemplary embodiment described with reference to FIG. 6 will now be described.

Referring to FIG. 7, the pixel PX of the present exemplary embodiment includes two of four second subpixels SP2, one of two first subpixels SP1, and one of two third subpixels SP3 connected to a third scan line SL3. The other two of the four second subpixels SP2, the other one of the two first subpixels SP1, and the other one of the two third subpixels SP3 are connected to a fourth scan line SL4.

Each of the third scan line SL3 and the fourth scan line SL4 may be, for example, a scan line among wires in the circuit portion. The third scan line SL3 and the fourth scan line SL4 switch the pixel circuit of the circuit portion to selectively turn on at least one of the two first subpixels SP1, the four second subpixels SP2, and the two third subpixels SP3.

In this case, the sixth data line DL6 and the eighth data line DL8 transmit the same data voltage to the two first subpixels SP1, the seventh data line DL7 transmits the same data voltage to the four second subpixels SP2, and the sixth data line DL6 and the eighth data line DL8 transmit the same data voltage to the two third subpixels SP3.

The sixth data line DL6 and the eighth data line DL8 may transmit a data voltage corresponding to one half of red luminance to be emitted from one pixel PX to the two first subpixels SP1. The seventh data line DL7 may transmit a data voltage corresponding to one fourth of green luminance to be emitted from one pixel PX to the four second subpixels SP2. The sixth data line DL6 and the eighth data line DL8 may transmit a data voltage corresponding to one half of blue luminance to be emitted from one pixel PX to the two third subpixels SP3.

As such, in the head-mounted display device according to the present exemplary embodiment, even though one pixel PX includes eight subpixels (two first subpixels SP1, the four second subpixels SP2, and the two third subpixels SP3), since only three data lines including the sixth data line DL6, the seventh data line DL7, and the eighth data line DL8 corresponding to red, green, and blue light are included therein, an additional data line and an additional data driver for generating an additional data voltage are not required.

In addition, in the head-mounted display device according to the present exemplary embodiment, even though one pixel PX includes the eight subpixels (two first subpixels SP1, the four second subpixels SP2, and the two third subpixels SP3), since the two first subpixels SP1, the four second subpixels SP2, and the two third subpixels SP3 are selectively turned on by only two scan lines including the third scan line SL3 and the fourth scan line SL4, an additional scan line is not required.

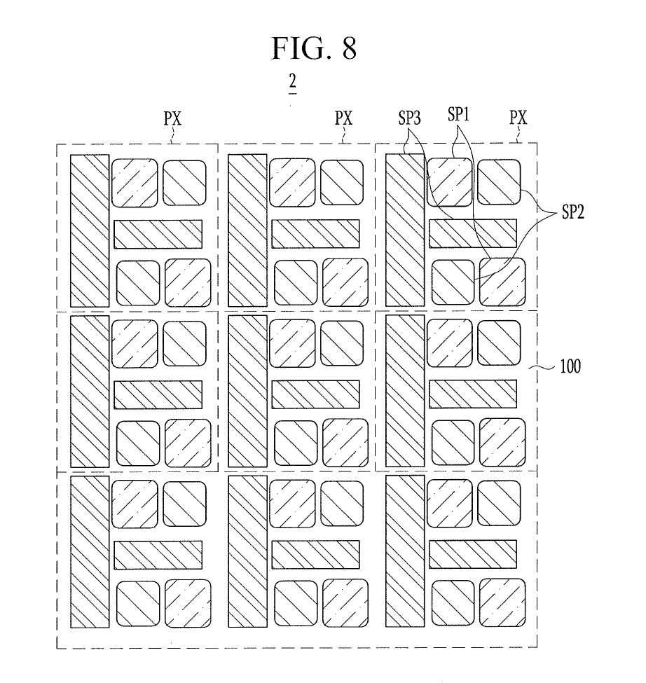

FIG. 8 illustrates a top plan view of another embodiment of a display panel 2 of a head-mounted display device. Portions different from the head-mounted display device according to the exemplary embodiment described above will be described.

Referring to FIG. 8, the display panel 2 includes a pixel layer 100 including a plurality of pixels PX. Each of the pixels PX includes a plurality of first subpixels SP1, a plurality of second subpixels SP2, and a plurality of third subpixels SP3. The first subpixels SP1, the second subpixels SP2, and the third subpixels SP3 emits light to display part of an image. For example, the pixel PX includes two first subpixels SP1, two second subpixels SP2, and two third subpixels SP3, e.g., six subpixels form one pixel PX.

The number of pixels PX may be, for example, 1280*720, 1366*768, 1920*1080, or 3840*2160 in the display panel 2, with each pixel PX including the two first subpixels SP1, the two second subpixels SP2, and the two third subpixels SP3. For example, the first subpixel SP1 emits red light, the second subpixel SP2 emits green light, and the third subpixel SP3 emits blue light.

One of the two third subpixels SP3 is between the two first subpixels SP1 and between the two second subpixels SP2. In one embodiment, the first subpixels SP1, the second subpixels SP2, and the third subpixels SP3 may be disposed in various ways or positions.

As described above, in the head-mounted display device according to the present exemplary embodiment, since each pixel PX in the display panel 2 includes two first subpixels SP1, two second subpixels SP2, and two third subpixels SP3 (e.g., six subpixels), the number of PPI of the display panel 2 is recognized as relatively high by the user when the image displayed on the display panel 2 is enlarged by the optical system for viewing. Thus, according to the current exemplary embodiment, it is possible to provide a head-mounted display device with improved resolution.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

What is claimed is:

1. A head-mounted display device, comprising:
a case;
a display panel in the case to display an image; and
an optical system to enlarge the image, wherein:
the display panel includes a plurality of pixels;
each of the pixels includes a plurality of first subpixels, a plurality of second subpixels, and a plurality of third subpixels;
the first subpixels are connected to each other, the second subpixels are connected to each other, and the third subpixels are connected to each other; and
the first subpixels, the second subpixels, and the third subpixels are to emit light of different colors.

2. The head-mounted display device as claimed in claim 1, wherein each of the pixels includes two of the first subpixels, four of the second subpixels, and two of the third subpixels.

3. The head-mounted display device as claimed in claim 2, wherein:
the four second subpixels surround one of the two first subpixels, and
the two first subpixels and the two third subpixels alternately surround one of the four second subpixels.

4. The head-mounted display device as claimed in claim 3, wherein:
one of the two first subpixels is connected to a first data line,
one of the four second subpixels is connected to a second data line, and
one of the two third subpixels is connected to a third data line.

5. The head-mounted display device as claimed in claim 4, wherein:
one of the four second subpixels and the two first subpixels are connected to a first scan line, and
another of the four second subpixels and the two third subpixels are connected to a second scan line.

6. The head-mounted display device as claimed in claim 3, wherein:
one of the two first subpixels is connected to a sixth data line and the other of the two first subpixels is connected to an eighth data line,
the four second subpixels are connected to a seventh data line,
one of the two third subpixels is connected to the sixth data line and the other of the two third subpixels is connected to the eighth data line.

7. The head-mounted display device as claimed in claim 6, wherein
two of the four second subpixels, one of the two first subpixels, and one of the two third subpixels are connected to a third scan line, and
the other two of the four second subpixels, the other one of the two first subpixels, and the other one of the two third subpixels are connected to a fourth scan line.

8. The head-mounted display device as claimed in claim 1, wherein
the first subpixels are to emit red light,
the second subpixels are to emit green light, and
the third subpixels are to emit blue light.

9. The head-mounted display device as claimed in claim 1, wherein the display panel includes:
a substrate;
a circuit portion on the substrate;
a plurality of electrodes connected to the circuit portion;
a pixel defining layer including a plurality of pixel openings;
a common electrode facing the electrodes; and
a plurality of organic emission layers, each of the organic emission layers between one of the electrodes and the common electrode, wherein the first subpixels, the second subpixels, and the third subpixels are to emit the light of the different colors through respective ones of the pixel openings, and wherein sizes of the first subpixels, the second subpixels, and the third subpixels correspond to sizes of the respective ones of the pixel openings.

10. The head-mounted display device as claimed in claim 1, wherein:
the display panel includes a first display panel corresponding to a left-eye position and a second display panel corresponding to a right-eye position,
the optical system includes a first optical system corresponding to the first display panel and a second optical system corresponding to the second display panel,
a length of the first display panel is longer than a diameter of the first optical system, and
a length of the second display panel is longer than a diameter of the second optical system.

11. The head-mounted display device as claimed in claim 10, wherein:
a distance from the first optical system to the first display panel is larger than a distance from the left-eye position to the first optical system, and
a distance from the second optical system to the second display panel is larger than a distance from the right-eye position to the second optical system.

12. The head-mounted display device as claimed in claim 1, wherein each of the pixels includes two of the first subpixels, two of the second subpixels is two, and two of the third subpixels.

13. The head-mounted display device as claimed in claim 12, wherein
one of the two third subpixels is between the two first subpixels and between the two second subpixels.

14. A pixel, comprising:
a plurality of first subpixels;
a plurality of second subpixels; and
a plurality of third subpixels, wherein:
the first subpixels are connected to each other, the second subpixels are connected to each other, and the third subpixels are connected to each other; and
the first subpixels, the second subpixels, and the third subpixels are to emit light of different colors.

15. The pixel as claimed in 14, including:
two of the first subpixels,
four of the second subpixels, and
two of the third subpixels.

16. The pixel as claimed in 14, including:
two of the first subpixels,
two of the second subpixels, and
two of the third subpixels.

17. The pixel as claimed in 14, wherein at least two of the first subpixels, the second subpixels, or the third subpixels have different areas.

18. The pixel as claimed in 14, wherein at least two of the first subpixels, the second subpixels, or the third subpixels have different shapes.

19. The pixel as claimed in 14, wherein at least two of the first subpixels, the second subpixels, and the third subpixels are spaced at different distances.

20. The pixel as claimed in 14, wherein at least one of the second subpixels is between adjacent ones of the first subpixels or adjacent ones of the second subpixels.
